(19) United States
(12) Patent Application Publication
(10) Pub. No.: US 2014/0159120 A1
(43) Pub. Date: Jun. 12, 2014

(54) Conformal Doping

(71) Applicant: INTERMOLECULAR, INC., San Jose, CA (US)

(72) Inventor: Khaled Ahmed, Anaheim, CA (US)

(73) Assignee: INTERMOLECULAR, INC., San Jose, CA (US)

(21) Appl. No.: 13/706,619

(22) Filed: Dec. 6, 2012

(51) Int. Cl. H01L 21/225; H01L 29/36

(52) U.S. Cl. CPC H01L 21/2258; H01L 29/36
USPC 257/213; 438/547; 438/535; 156/345.31

(57) ABSTRACT

Methods for doping a three-dimensional semiconductor structure are disclosed. A conformal coating is formed on the three-dimensional semiconductor structure by Atomic Layer Deposition, and subsequent annealing causes dopant atoms to migrate into the three-dimensional semiconductor structure. Any residual conformal coating is then removed by etching. The semiconductor can be a type IV semiconductor such as Si, SiC, SiGe, or Ge, for which Sb and Te are suitable dopants. Sb and Te can be provided from a Ge₂Sb₂Te₅ conformal coating. The semiconductor can also be a type III-V semiconductor such as InGaAs, GaAs, InAs, or GaSb, for which Sn and S are suitable dopants. Sn and S can be provided from a SnS conformal coating. The dopant concentration can be adjusted by precise control over the number of monolayers deposited in a conformal coating layer deposited by ALD.

### FIELD OF THE INVENTION

One or more embodiments of the present invention relate to methods of manufacture of semiconductor devices.

### BACKGROUND

As device size continues to shrink in the fabrication of integrated circuits, three-dimensional device structures are becoming increasingly common. These structures are characterized by high aspect ratios where the physical height of a feature on a device can be several times the feature width. In many cases, these structures comprise a semiconductor that must be doped to achieve the desired electrical characteristics.

One frequently used approach to such doping is the use of ion implantation. However, high densities, high pitches and/or large vertical aspect ratios can make the process of ion implantation problematic, because only a very small range of implant angles are available, and it can be difficult to uniformly dope the active volume of the structure. Many known methods of performing conformal ion implants use multiple steps of angled beam-line ion implants to obtain three-dimensional implantation coverage. In these known methods, a target is physically positioned at a plurality of angles relative to the ion beam for predetermined times so that a plurality of angled implants are performed. However, performing multiple beam-line angled implants can greatly reduce the throughput of the implantation by a factor equal to the number of ion implants performed. This method of conformal doping has been successfully used for some low density structures made for research and development purposes, but is not practical for manufacturing of most devices.

For selected dopants such as S, it is also possible to anneal a structure in an atmosphere containing the dopant atom (e.g., H₂S for S doping), where the dopant is contacted with all surfaces of a substrate in equal concentration. However, such methods are limited to dopant atoms having compatible precursor gases. In addition, these methods may not provide sufficiently precise control over the final dopant concentration.

U.S. Patent Application Publication No. 2009/0008577 to Walther and U.S. Pat. No. 7,524,743 to Gupta et al. disclose methods of “conformal doping” wherein dopant materials are deposited on both planar and non-planar structures, optionally with additional barrier layers. The dopant atoms are driven into the underlying semiconductor structure by means of plasmas generated near the surface.

### SUMMARY OF THE INVENTION

Methods for doping a three-dimensional semiconductor structure are disclosed. A conformal coating is formed on the three-dimensional semiconductor structure by Atomic Layer Deposition, and subsequent annealing causes dopant atoms to migrate into the three-dimensional semiconductor structure. Any residual conformal coating is then removed by etching. The semiconductor can be a type IV semiconductor such as Si, SiC, SiGe, or Ge, for which Sb and Te are suitable dopants. Sb and Te can be provided from a Ge₂Sb₂Te₅ conformal coating. The semiconductor can also be a type III-V semiconductor such as InGaAs, GaAs, InAs, or GaSb, for which Sn and S are suitable dopants. Sn and S can be provided from a SnS conformal coating. The dopant concentration can be adjusted by precise control over the number of monolayers deposited in a conformal coating layer deposited by ALD.

The annealing can be performed by Rapid Thermal Annealing or laser annealing. The etching can be performed by a wet process or by reactive ion etching. The etching can be selective for the conformal coating (“stop on semiconductor”).

Systems can be provided to enable practicing the above methods without removing a substrate from a vacuum environment. A cluster tool can be provided with a plurality of processing chambers and a substrate transport system operable to move the substrate among the plurality of processing chambers. One of the plurality of processing chambers can be operable to clean the substrate to remove any surface oxide layer; one of the plurality of processing chambers can be operable to deposit layers by atomic layer deposition; one of the plurality of processing chambers can be operable to anneal the layers; and one of the plurality of processing chambers can operable to etch the layers.

A semiconductor device can be made incorporating the three-dimensional structure conformally-doped as described above. Examples of useful devices with doped three-dimensional structures include transistors such as field effect transistors (“FETs”), including FinFETs, nanowire FETs, and tunnel FETs.

### BRIEF DESCRIPTION OF THE DRAWINGS

FIG. 1 shows the process flow for doping a type IV semiconductor from a conformal layer applied by ALD.

FIG. 2 shows the process flow for doping a type III-V semiconductor from a conformal layer applied by ALD.

FIG. 3 shows a cluster tool which can be used to implement the processes described herein.

### DETAILED DESCRIPTION

Before the present invention is described in detail, it is to be understood that unless otherwise indicated this invention is not limited to specific semiconductor devices. Exemplary embodiments will be described for three-dimensional devices such as FinFETs, but other devices can also be fabricated using the methods disclosed. It is also to be understood that the terminology used herein is for the purpose of describing particular embodiments only and is not intended to limit the scope of the present invention.

It must be noted that as used herein and in the claims, the singular forms “a,” “and” and “the” include plural referents unless the context clearly dictates otherwise. Thus, for example, reference to “a layer” includes two or more layers, reference to “a dopant” refers to two or more dopants, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. Where the modifier “negligible” is used, any change in the modified quantity is small enough to have no measurable effect on device performance. Where the modifier “about” or “approximately” is used, the stated quantity can vary by up to 10%. Where the modifier “substantially equal to” is used, the two quantities may vary from each other by no more than 5%.

### Definitions:

The term “FinFET” as used herein refers to a field effect transistor (“FET”), typically having feature sizes of less than 28 nm, which includes a semiconductor “fin” that extends the semiconductor region between the source and drain above the semiconductor substrate. Fins typically have a high aspect ratio wherein the height of the fin is at least three times the width.

Three-dimensional structures are becoming common in current generation semiconductor devices with feature sizes below 28 nm. Examples include FinFET transistors (“FET”=“field effect transistor”; FinFETS include “tri-gate” transistors) having a gate structure comprising a “fin” with a height larger than its width, tunnel FETs, and nanowire transistors. These structures can include doped semiconductors, and the doping is often performed after the structure is formed, using ion implantation from one or more angled directions. These doping processes can result in uneven distribution of dopant atoms through the fin which, in turn, can result in undesirable current crowding (concentration of current density is selected regions rather than uniformly distributed). Ion implantation also requires the use of high-energy ions which can damage the surface being doped. These problems can be avoided by conformal doping.

Methods and systems for conformally doping three-dimensional semiconductor structures are disclosed. The methods generally comprise precleaning (e.g., with atomic hydrogen), then using atomic layer deposition (ALD) to deposit a thin film that contains dopants on the semiconductor using atomic layer deposition, then using thermal annealing to drive the dopants from the film into the semiconductor, i.e., the dopant atoms migrate into the three-dimensional semiconductor structure. The conformal layer can be made with precise thickness and composition comprising suitable dopant atoms. Typical layer thicknesses of 1-10 monolayers are sufficient to provide enough dopant atoms for structures having widths of 10-25 nm. The thermal anneal (e.g., laser annealing or rapid thermal anneal [RTA]) then drives the dopants from the conformal layer into the semiconductor. The conformal layer can then be removed, for example, by wet etching or reactive ion etching (stop on semiconductor) in such a manner that it provides negligible etching of the semiconductor structure.

Laser annealing can employ a variety of specific lasers and process parameters. Examples of suitable lasers include semiconductor diode lasers (e.g. AlGaAs/AlGaAs/GaAs: 700-900 nm; GaInP/AlGaInP/GaAs: 660-690 nm), Nd:YAG (diode-pumped solid state, rod or flashlamp) frequency-doubled to 532 nm; and Ti-Sapphire (tunable) (690-1040 nm). The laser can be operated in either continuous or pulsed output mode. These lasers can have peak power output up to about 300 kW. For surface treatment, such as heating a conformal coating and driving dopant migration into the underlying semiconductor layers, the wavelength of the laser can be selected for strong absorption, and the energy of the laser can be delivered only to the near surface region of the layer (i.e. <0.1 μm). Therefore, it is possible to raise the temperature of the surface to temperatures well above the glass transition temperature of the substrate without damaging the substrate or underlying layers. Furthermore, the laser beam can be focused into desirable shapes and sizes that can be used to target specific structures on the device. Examples of such useful shapes comprise circles, rectangles, squares, ovals, etc.

Laser annealing can be performed using continuous heating at 0.5-5 J/cm² for 4-5 s, or by irradiating the surface of the semiconductor device with laser pulses of varying pulse lengths. The pulse width can vary from femtoseconds, to nanoseconds, microseconds and milliseconds, depending on the energy and amount of localized heating desired at a particular location on the semiconductor structure.

The use of lasers for annealing may have a number of benefits. The use of lasers allows the semiconductor layers to be heated to temperatures close to their melting point without damaging other layers of the structure due to the shallow absorption of the laser beam. Laser annealing can improve the compositional homogeneity of the semiconductor layers due to increased atomic diffusion at the elevated temperatures. The use of lasers for annealing the semiconductor layers may allow non-equilibrium phases to be quenched due to the short timescales that are typical of laser materials processing. In the instant invention, laser annealing enables atomic migration locally from the conformal layer into the surface of the three-dimensional semiconductor structure without raising the temperature of the entire substrate.

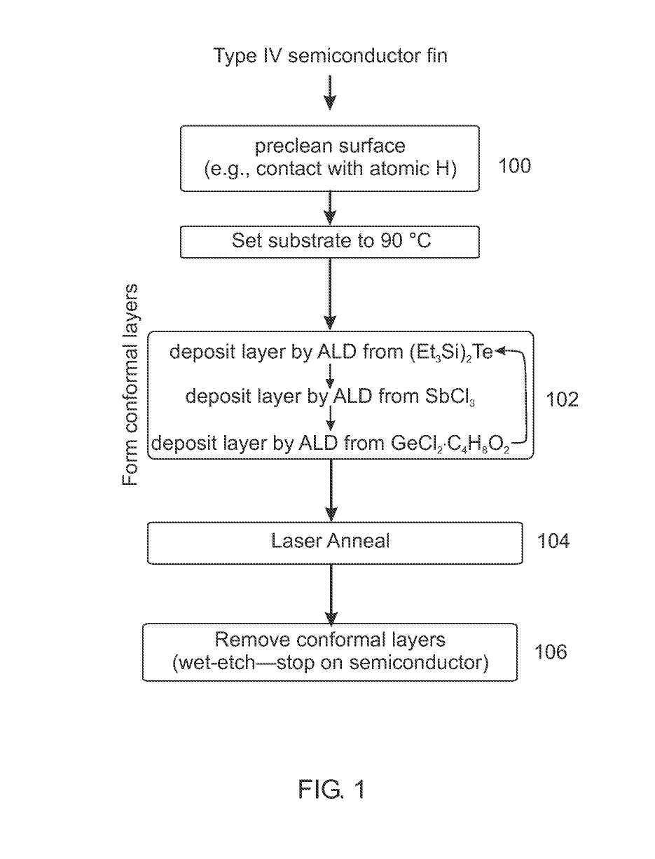

In some embodiments, the semiconductor comprises a type IV semiconductor such as, for example, silicon, silicon-carbon, silicon-germanium, or germanium. Sb and Te are suitable for use as n-type dopants in these semiconductors. Sb and Te atoms can be provided from a conformal layer of Ge₂Sb₂Te₅ (“GST”), for example. This process is illustrated in FIG. 1, for the doping of a component of a semiconductor device such as a FinFET. After a precleaning step 100, the conformal layer can be deposited by one or more cycles of ALD steps 102. Additional cycles of ALD can be performed to prepare a conformal coating of thickness of from about 1 to about 10 monolayers. A subsequent RTA or laser annealing step 104 can drive the dopants from the GST into the semiconductor by diffusion. Typical process conditions for RTA are 900° C. for 1-10 s. Typical laser anneal process conditions are 0.5-5 J/cm².

GST is a well-known material commonly used as a phase-change memory material, although the phase-change behavior is not exploited here. The GST layer can be deposited, for example, by ALD using sequential exposures of the semiconductor substrate to precursor gases comprising (Et₃Si)₂Te, SbCl₃ and GeCl₂.C₄H₈O₂ at 90° C. This process been described by Ritala et al. (“Atomic Layer Deposition of Germanium Antimony Telluride Thin Films,” European Symposium on Phase Change and Ovonic Science (E\PCOS), 151-56, 2009 which is incorporated herein by reference), and has been shown to produce layers that can be precisely controlled to a fraction of a monolayer and deposited conformally on high-aspect-ratio structures.

The remaining GST layer can then be etched away, as shown in FIG. 1, step 106. Various etching methods can be used including wet etching and plasma etching (reactive ion etching [RIE]: Feng et al., “Reactive Ion Etching of Ge₂Sb₂Te₅ in CHF_{3/}O₂ Plasma for Nonvolatile Phase-Change Memory Device,” Electrochemical and Solid-State Letters, 10 (5) D47-50, 2007 which is incorporated herein by reference) showed that RIE can be selective for etching the GST layer relative to SiO₂.

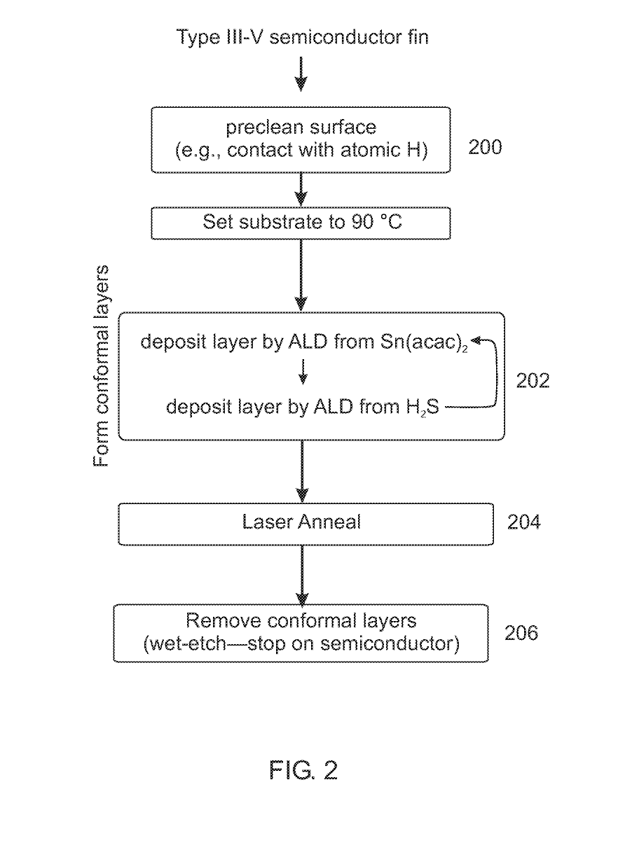

In some embodiments, the semiconductor comprises a III-V semiconductor such as, for example, GaAs, InAs, or InGaAs. Sn and S are suitable for use as n-type dopants in these semiconductors. The process is illustrated in FIG. 2. Sn and S atoms can be provided from a conformal layer of SnS. After a precleaning step 200, the conformal layer can be deposited by one or more cycles of ALD steps 202. Additional cycles of ALD can be performed to prepare a conformal coating of thickness of from about 1 to about 10 monolayers. A subsequent RTA or laser annealing step 204 can drive the dopants from the SnS layer into the semiconductor by diffusion, i.e., the dopant atoms migrate into the three-dimensional semiconductor structure. The remaining SnS layer can then be etched away in step 206. Various etching methods can be used including wet etching and plasma etching.

The SnS film can be deposited, for example, by ALD using sequential exposures of the semiconductor to tin(II) 2,4-pentanedionate (Sn(acac)₂, 95+%) and hydrogen sulfide (H₂S, 99.5+%). The Sn(acac)₂ can be placed in a bubbler and heated to ˜105° C. The Sn(acac)₂ can be dosed by sending N₂ gas over the headspace of the precursor in the bubbler. The pressures of the Sn(acac)₂ and H₂5 gases can be ˜10 and ˜150 mTorr, respectively. An exemplary process is described in Kim and George, “Tin Monosulfide Thin Films Grown by Atomic Layer Deposition Using Tin 2,4-Pentanedionate and Hydrogen Sulfide,” J. Phys. Chem. C 2010, 114, 17597-603, which is incorporated herein by reference.

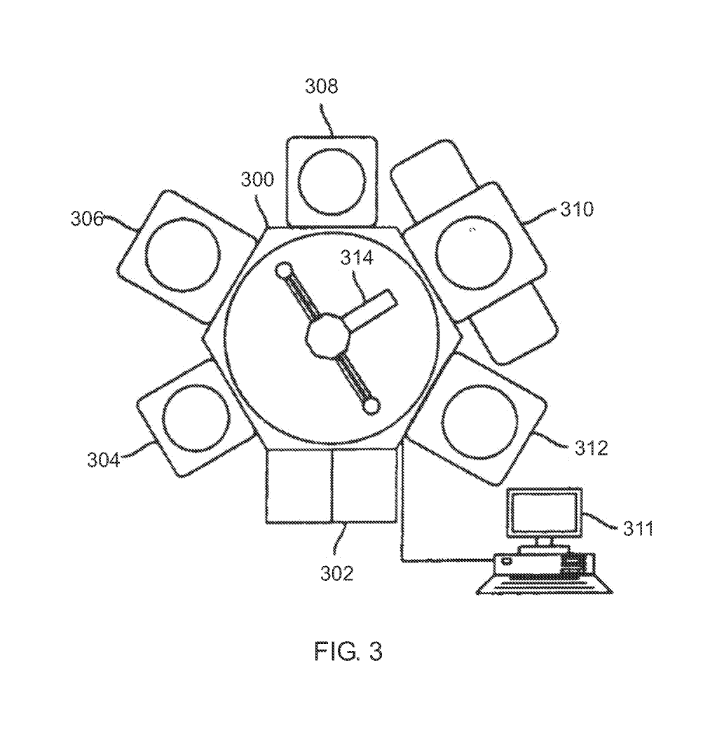

In some embodiments, a cluster tool is used to allow substrates to be processed sequentially in different processing chambers with different processing methods without removing the substrates from a sealed vacuum environment. FIG. 3 illustrates such a cluster tool. A cluster tool 300 includes a plurality of processing chambers 304-312 and a substrate transport system 314 operable to move the substrate among the plurality of processing chambers. For example, one processing chamber 304 can be configured for precleaning a semiconductor surface, for example, by contacting the surface with atomic hydrogen. A second processing chamber 306 can be configured for the ALD processing described above. A third processing chamber 308 can be configured for RTA or laser annealing. A fourth processing chamber 310 can be configured for wet etching or reactive ion etching. A fifth metrology chamber 312 can be configured for monitoring the cleaning, ALD, annealing and etching processes. A control computer 311 can be configured to control the process flow and operating parameters.

It will be understood that the descriptions of one or more embodiments of the present invention do not limit the various alternative, modified and equivalent embodiments which may be included within the spirit and scope of the present invention as defined by the appended claims. Furthermore, in the detailed description above, numerous specific details are set forth to provide an understanding of various embodiments of the present invention. However, one or more embodiments of the present invention may be practiced without these specific details. In other instances, well known methods, procedures, and components have not been described in detail so as not to unnecessarily obscure aspects of the present embodiments.

What is claimed is:

1. A method for doping a three-dimensional semiconductor structure comprising
forming a conformal coating comprising one or more dopant atoms on the three-dimensional semiconductor structure by Atomic Layer Deposition,
annealing the conformal coating and three-dimensional semiconductor structure such that the one or more dopant atoms migrate into the three-dimensional semiconductor structure, and
removing any residual conformal coating by etching.

2. The method of claim 1, wherein the semiconductor comprises a type IV semiconductor.

3. The method of claim 2, wherein the type IV semiconductor comprises Si, SiC, SiGe, or Ge.

4. The method of claim 2, wherein the one or more dopant atoms comprise Sb and Te.

5. The method of claim 2, wherein the conformal coating comprises Ge₂Sb₂Te₅.

6. The method of claim 1, wherein the semiconductor comprises a type III-V semiconductor.

7. The method of claim 6, wherein the type III-V semiconductor comprises InGaAs, GaAs, InAs, or GaSb.

8. The method of claim 6, wherein the one or more dopant atoms comprise Sn and S.

9. The method of claim 6, wherein the conformal coating comprises SnS.

10. The method of claim 1, wherein the conformal coating has a thickness of from about 1 to about 10 monolayers.

11. The method of claim 1, wherein the annealing is by Rapid Thermal Annealing.

12. The method of claim 1, wherein the annealing is by laser annealing.

13. The method of claim 1, wherein the etching is by a wet process.

14. The method of claim 1, wherein the etching is by reactive ion etching.

15. The method of claim 1, wherein the etching is selective for the conformal coating such that negligible etching of the semiconductor structure occurs.

16. A system for uniformly doping a three-dimensional semiconductor structure comprising
a cluster tool comprising a plurality of processing chambers and a substrate transport system operable to move the substrate among the plurality of processing chambers;
wherein one of the plurality of processing chambers is operable to clean the substrate to remove any surface oxide layer;
wherein one of the plurality of processing chambers is operable to deposit layers by atomic layer deposition;
wherein one of the plurality of processing chambers is operable to anneal the layers; and
wherein one of the plurality of processing chambers is operable to etch the layers.

17. A semiconductor device comprising a three-dimensional structure doped by the method of claim 1.

18. The semiconductor device of claim 19, wherein the device is a FinFET, nanowire FET, or tunnel FET.
